(19) United States
(12) Patent Application Publication
(10) Pub. No.: US 2026/0128248 A1
(43) Pub. Date: May 7, 2026

(54) GROUND FAULT DETECTION CIRCUIT BREAKER

(71) Applicant: Chengli LI, Suzhou (CN)

(72) Inventors: Chengli Li, Suzhou (CN); Xiaoming Zhang, Suzhou (CN); Long Chen, Suzhou (CN); Hao Tian, Suzhou (CN)

(73) Assignee: Chengli LI, Suzhou (CN)

(21) Appl. No.: 19/049,599

(22) Filed: Feb. 10, 2025

Related U.S. Application Data
(63) Continuation-in-part of application No. 18/941,159, filed on Nov. 8, 2024.

(30) Foreign Application Priority Data
Nov. 6, 2024 (CN) 202411572494.0
Jan. 27, 2025 (CN) 202510126163.2
Jan. 27, 2025 (CN) 202520175853.2

(51) Int. Cl. H01H 83/04; G01R 31/52; H01H 71/04; H01H 71/24

(52) U.S. Cl. CPC H01H 83/04; G01R 31/52; H01H 71/04; H01H 71/2481; H01H 2300/052

(57) ABSTRACT

A ground fault detection circuit breaker includes: a circuit breaker module, including a circuit breaker tripping rod having first and second positions for respectively disconnecting and connecting power connection between an input end and an output end; and a ground fault detection drive module, including a ground fault signal processing assembly, a ground fault signal detection assembly and a drive assembly. The drive assembly drives the circuit breaker tripping rod to move from a second position to a first position under control of the ground fault signal processing assembly, and includes a switch and a tripping coil assembly. The switch is mechanically linked to the tripping rod; it is in an open state when the tripping rod moves from the first position toward the second position before reaching a first intermediate position, and in a closed state before the tripping rod reaches a second intermediate position.

### BACKGROUND OF THE INVENTION

This invention relates to the field of leakage protection devices, and in particular, it relates to a ground fault detection circuit breaker device with ground fault protection functions and circuit breaker protection functions.

With the continuous improvement of living standards and people's safety awareness, products with ground fault leakage protection function are more widely used. Traditional ground fault leakage protection devices are usually combined with household wall sockets to detect leakage faults at the output end of the wall socket and control the device to trip and cut off the power to protect the user's electricity safety. More advanced ground fault leakage protection devices on the market (such as ground fault circuit interrupters (GFCI)) are mainly used for protection of small current appliances such as 20 amperes and below in household use. With the advancement of technology and changes in the power consumption environment, there is a need for leakage detection circuit interrupters that can match the circuit breaker, which can realize the functions of large current (above 20 amperes) leakage detection and disconnection, so as to be suitable for various applications such as mobile energy storage and high-power generators according to different needs.

### SUMMARY OF THE INVENTION

Based on the above needs, embodiments of the present invention provide a ground fault detection circuit breaker device that meet different application scenarios in a cost-effective and reliable manner.

In one aspect, the present invention provides a ground fault detection circuit breaker which includes: a circuit breaker module, having an input end configured to be coupled to a power supply, an output end configured to be coupled to an electrical load, and a circuit breaker tripping rod, the circuit breaker tripping rod having a first position in a disconnected state and a second position in a connected state, configured to respectively disconnect and connect a power connection between the input end and the output end; and a ground fault detection drive module, including a housing, a ground fault signal processing assembly, a ground fault signal detection assembly coupled to the ground fault signal processing assembly, and a drive assembly coupled to the ground fault signal processing assembly, wherein the ground fault signal processing assembly, the ground fault signal detection assembly and the drive assembly are disposed in the housing, wherein the drive assembly is configured to drive the circuit breaker tripping rod to move from the second position to the first position in response to control of the ground fault signal processing assembly, wherein the drive assembly includes a switch and a tripping coil assembly coupled to each other, wherein the switch is mechanically linked to the circuit breaker tripping rod, and is configured to be in an open state when the circuit breaker tripping rod moves from the first position toward the second position before reaching a first intermediate position, and be in a closed state when the circuit breaker tripping rod moves further and before reaching a second intermediate position.

Based on the above principles, embodiments of the present invention may include any one or more of the following optional features.

In some embodiments, the first intermediate position corresponds to one-fourth of a total amount of travel of the circuit breaker tripping rod from the first position to the second position, and the second intermediate position is located between the first intermediate position and the second position.

In some embodiments, the switch is a normally closed switch which is in the open state when subjected to a pushing force by the circuit breaker tripping rod and returns to the closed state after the pushing force is removed.

In some embodiments, the switch includes a stationary contact assembly and a moving contact assembly, wherein the stationary contact assembly includes a stationary contact plate and a stationary contact terminal fixed on the stationary contact plate, the moving contact assembly includes an elastic moving contact plate and a moving contact terminal fixed to one end of the elastic moving contact plate, and wherein the elastic moving contact plate is mechanically linked to the circuit breaker tripping rod to cause the moving contact terminal and the stationary contact terminal to either be separated from each other or contact each other, thereby placing the switch in the open state or the closed state.

In some embodiments, the switch is configured such that when in the closed state, the elastic moving contact plate maintains elastic deformation to provide a contact pressure to maintain the contact between the moving contact terminal and the stationary contact terminal.

In some embodiments, the housing includes a position limiting block, located on a side of the elastic moving contact plate away from the stationary contact assembly, and configured to limit a movement of the elastic moving contact plate.

In some embodiments, the drive assembly further includes a lever mechanically linked to the tripping coil assembly, wherein the lever is configured to be in a first position separated from the circuit breaker tripping rod and or in a second position abutting against the circuit breaker tripping rod in response to driving action of the tripping coil assembly.

In some embodiments, the trip coil assembly drives the lever to move in response to control of the ground fault signal processing assembly; and/or the trip coil assembly includes a coil winding coupled to the ground fault signal processing assembly and an iron core and a spring disposed in the coil winding, wherein the iron core is configured to reciprocate in the coil winding.

In some embodiments, the lever has a snap-fitting notch configured to snap-fit with the iron core, and is mechanically linked to the iron core to pivot to a first position or a second position; and/or the lever has a pivot hole attached to the housing of the ground fault detection drive module, wherein the lever is configured to pivot around the pivot hole.

In some embodiments, the lever has a tab with a pushing surface, and wherein a pivoting movement of the lever causes the pushing surface to abut against the circuit breaker tripping rod and drive the circuit breaker tripping rod to move from its second position to its first position to place the switch in the open state.

In some embodiments, the ground fault signal detection assembly includes at least one ground fault detection coil configured to detect a ground fault signal in the current-carrying wires which pass therethrough, and wherein the housing has a cavity to accommodate and fix the ground fault detection coil.

In some embodiments, the input end and the output end are coupled respectively to the power supply and the electrical load by the current-carrying wires.

In some embodiments, the housing further includes a through hole, which is concentric with an inner hole of the ground fault detection coil and configured to for the current-carrying wires to pass through.

In some embodiments, the ground fault detection drive module further includes power input terminals for providing power to the ground fault detection drive module.

In some embodiments, the ground fault detection drive module further includes an operating assembly, the operating assembly including at least a test assembly coupled to the switch and configured to generate a simulated leakage signal and a reset assembly configured to re-connect the input end and the output end.

In some embodiments, the ground fault detection drive module includes a control circuit board for mounting the ground fault signal processing assembly.

In some embodiments, the ground fault detection drive module further includes a display assembly configured to display a working status of the ground fault detection circuit breaker.

In some embodiments, the circuit breaker module and the ground fault detection drive module are connected and fixed to each other by a fixing device.

In some embodiments, the fixing device includes at least one of rivets, bolts, screws, snaps, connecting plates, and fixing blocks.

In another aspect, the present invention provides a ground fault detection circuit breaker, which includes: an input end and an output end, configured to be respectively coupled to a power supply and an electrical load; current-carrying wires connecting the input end and the output end; a circuit breaker unit, configured to disconnect and connect a power connection between the input end and the output end; a ground fault signal detection unit, including at least a ground fault detection coil configured to detect a leakage current on the current-carrying wires; a ground fault signal processing unit, including at least a ground fault detection chip configured to determine whether the leakage current exceeds a preset value, and to generate a ground fault signal when the leakage current exceeds the preset value; a drive unit, including a switch, a tripping coil assembly, and semiconductor switches coupled to each other, the drive unit being configured to drive the circuit breaker unit to operate in response to the ground fault signal to disconnect the input end from the output end; and a trip holding unit, which includes at least a holding capacitor, the holding capacitor being configured to keep the semiconductor switches in a conducting state.

In some embodiments, the trip holding unit further included a fault indicator, configured to issue a leakage fault indication in response to the ground fault signal.

In some embodiments, the ground fault detection circuit breaker further includes a self-test unit, coupled to the drive unit and configured to periodically test whether the ground fault signal processing unit is functioning normally, and generate a self-test fault signal when the ground fault signal processing unit fails to function normally.

In some embodiments, the ground fault detection circuit breaker further includes an operating unit, including at least a test button coupled to the switch and configured to generate a simulated leakage signal and a reset button configured to restore the semiconductor switches to a non-conducting state.

The ground fault detection circuit breaker device according to embodiments of the present invention combines the circuit breaker function with the ground fault detection driving function, providing personal safety protection and equipment and circuit protection through a dual protection mechanism. It can effectively provide power-off protection in the event of a leakage fault, is suitable for a variety of electrical equipment, and improves safety in use. The ground fault detection circuit breaker device has a simple structure, low cost, is easy to implement, has reliable performance, is suitable for automated production, and can be applied to various occasions.

### BRIEF DESCRIPTION OF DRAWINGS

Other features and advantages of the present invention may be understood from the embodiments described below with reference to the drawings.

FIG. 1A illustrates the exterior appearance of a ground fault detection circuit breaker device according to an embodiment of the present invention.

FIG. 1B is an exploded view of the ground fault detection circuit breaker device shown in FIG. 1A.

FIG. 2A illustrates a ground fault detection drive module in the ground fault detection circuit breaker device shown in FIG. 1A, and shows the assembly relationship between the lever and the housing.

FIG. 2B is an exploded view of the ground fault detection drive module shown in FIG. 2A.

FIG. 3A is an exploded view of a tripping coil assembly in the ground fault detection drive module.

FIG. 3B illustrates the lever.

FIG. 4A is a schematic diagram of a circuit breaker module in the ground fault detection circuit breaker device shown in FIG. 1A.

FIG. 4B illustrates a ground fault detection drive module, respectively showing the mating surfaces of the circuit breaker module and the ground fault detection drive module.

FIG. 5A illustrates the positions of various components of the ground fault detection circuit breaker device when the device is in an initial disconnected state. FIG. 5B is an enlarged view of area A in FIG. 5A.

FIG. 5C illustrates the positions and states of various components of the ground fault detection circuit breaker device during a process from an initial disconnected state to a normal connected state. FIG. 5D is an enlarged view of area B in FIG. 5C.

FIG. 6A illustrates the states of various components of the circuit breaker module when the circuit breaker tripping rod has moved a quarter of its total amount of travel. FIG. 6B is an enlarged view of area C in FIG. 6A.

FIG. 6C illustrates the state in which the switch of the ground fault detection drive module is closed before the input end is connected to the output end. FIG. 6D is an enlarged view of area D in FIG. 6C.

FIG. 7A illustrates the positions and states of various components of the ground fault detection circuit breaker device when the device is in a normal connected state.

FIG. 7B is an enlarged view of area E in FIG. 7A.

FIG. 7C shows the state after the ground fault detection circuit breaker device detects a fault signal, where the tripping coil assembly drives the lever to place the circuit breaker tripping rod and the switch in a disconnected state. FIG. 7D is an enlarged view of area F in FIG. 7C.

FIG. 8A illustrates the exterior appearance of a ground fault detection circuit breaker device with a two-pole circuit breaker module according to another embodiment of the present invention.

FIG. 8B illustrates the exterior appearance of a ground fault detection circuit breaker device with a three-pole circuit breaker module according to another embodiment of the present invention.

FIG. 9 is a circuit diagram showing the principle of a ground fault detection circuit breaker device according to an embodiment of the present invention.

### DETAILED DESCRIPTION OF THE INVENTION

The implementation and use of the embodiments are discussed in detail below. However, it should be understood that the specific embodiments discussed are merely exemplary of specific ways to implement and use the present invention, and are not intended to limit the scope of the present invention. When describing the structural positions of the various components, such as up, down, top, bottom, etc., the expressions of directions are not absolute, but relative. When the various components are arranged as shown in the figure, these directional expressions are appropriate, but when the positions of the various components in the figure change, these directional expressions also change accordingly.

In the descriptions below, terms such as “comprising”, “including”, “containing”, “having”, etc. are intended to be open-ended and do not exclude elements, step or components not specifically listed.

In this disclosure, unless otherwise indicated, terms such as “mount”, “connect”, “couple”, “link” etc. should be understood broadly; for example, they may be fixed connections, or removable or detachable connections, or integrally connected for integrally formed; they may be directly connected, or indirectly connected via intermediate parts, and may refer to internal connection of two components or mutual interactions of two components. Those skilled in the relevant art can readily understand the meaning of these terms as used in this disclosure based on the specific description and context.

In this disclosure, unless specifically indicated, terms such as “first”, “second”, etc. do not connote a temporal or spatial sequence or a particular number of parts.

It has been recognized that traditional circuit breakers cannot provide power-off protection in the event of leakage, and the existing leakage protection devices have limited application scenarios. In order to meet the more diversified needs of consumers, such as the need for products suitable for various application scenarios such as high current scenarios, embodiments of the present invention provide a ground fault detection circuit breaker device that combines the circuit breaker function and the ground fault detection drive function, and provides a dual protection mechanism to offer protection for personal safety and for equipment and circuits, making the ground fault protection device safer, more reliable and more widely used.

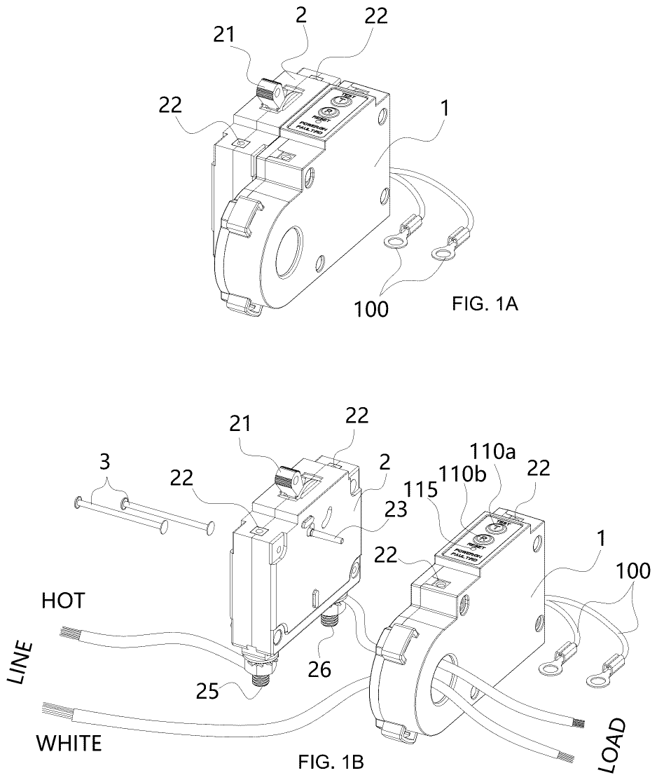

Specifically, referring to FIGS. 1A and 1B, a ground fault detection circuit breaker device according to an embodiment of the present invention includes a ground fault detection drive module 1 and a circuit breaker module 2. The circuit breaker module 2 includes an input end 25 and an output end 26, where the input end 25 is configured to be coupled to a power supply, and the output end 26 is configured to be coupled to an electrical load. The circuit breaker module 2 has a circuit breaker assembly that can be operated to connect or disconnect the input end 25 and the output end 26. In the illustrated embodiment, the circuit breaker assembly may include an operating handle 21 and a circuit breaker tripping rod 23, where the operating handle 21 is configured to move between an initial disconnecting position and a final connecting position, and to drive the circuit breaker tripping rod 23 to move between a first position and a second position. When the operating handle 21 is in the initial disconnecting position, the circuit breaker tripping rod 23 is correspondingly in its first position, and the input end 25 and the output end 26 are in a disconnected state; when the operating handle 21 is moved from the initial disconnecting position to the final connecting position, the circuit breaker tripping rod 23 is driven to its second position, so that the input end 25 and the output end 26 are in a connected state and form an electrical connection. Thereafter, according to the working principle of embodiments of the present invention, if the circuit breaker tripping rod 23 is placed in its first position, the input end 25 and the output end 26 of the circuit breaker module 2 will be disconnected, and the operating handle 21 can be restored to the initial disconnecting position at this time. Even if for some reason the operating handle 21 is restricted to the final connecting position, the input end 25 and the output end 26 can still be disconnected. When the circuit breaker tripping rod 23 is placed in its first position, even if the operating handle 21 moves from the initial disconnecting position to the final connecting position, it cannot cause the input end 25 and the output end 26 to be connected. In this way, the working characteristic of the circuit breaker device 2 is utilized in combination with the functional characteristics of the ground fault detection drive device 1 to achieve ground fault circuit breaking protection function under conditions of large currents, which will be described in detail below.

Advantageously, when the input end 25 and the output end 26 are in a connected state or a closed state, the circuit breaker tripping rod 23 can be driven by the ground fault detection drive module 1 to place the circuit breaker tripping rod 23 in its first position to disconnect the input end 25 and the output end 26, which will be described in detail below. In addition, the circuit breaker module 2 also includes at least one mounting unit 22, for mounting and fixing the circuit breaker module 2 to a desired position or component. Similarly, the ground fault detection drive module 1 also includes at least one mounting unit 22, for mounting the ground fault detection drive module 1 to a desired position or component, as shown in FIG. 1B. The mounting unit 22 includes but is not limited to screws, bolts, rails, etc., such as the panel bolts shown in the figure.

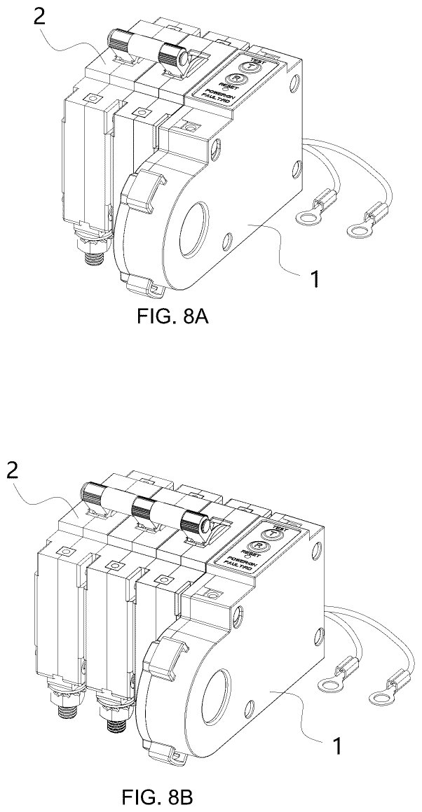

Depending on different needs, the ground fault detection circuit breaker device according to embodiments of the present invention may include at least a one pole circuit breaker module 2. For example, in the embodiment shown in FIGS. 1A and 1B, the one-pole circuit breaker module 2 and the ground fault detection drive module 1 may be connected and fixed to each other by a fixing device 3, such as shown in FIG. 1B. The fixing device 3 includes, for example, but is not limited to rivets, bolts, screws, snaps, connecting plates or fixing blocks and other components suitable for fixing. FIG. 8A exemplarily shows a ground fault detection circuit breaker device formed of a two-pole circuit breaker module 2 and a ground fault detection drive module 1. FIG. 8B exemplarily shows a ground fault detection circuit breaker device composed of a three-pole circuit breaker module 2 and a ground fault detection drive module 1. It should be understood that the number of circuit breaker modules is not limited here.

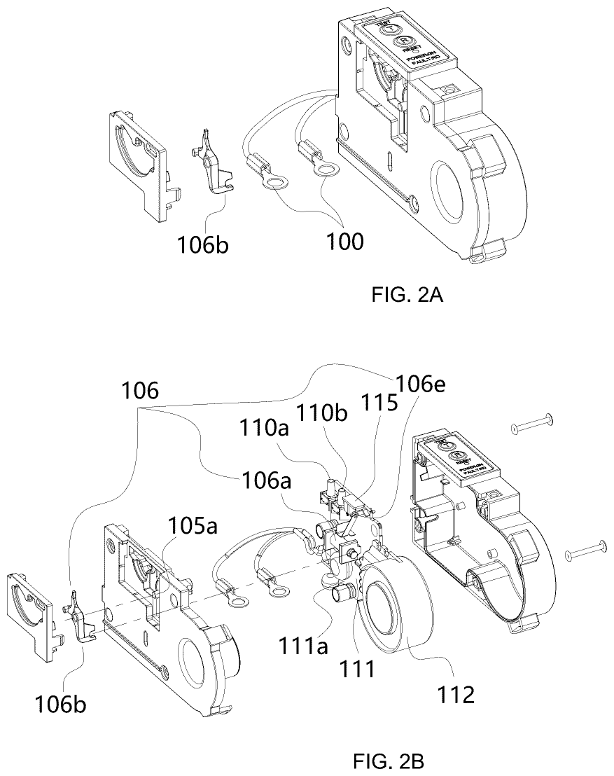

FIGS. 2A and 2B show a ground fault detection and drive module 1 and its main components according to an embodiment of the present invention. The ground fault detection and drive module 1 is configured to detect a ground fault at the output end. When a ground fault is detected, the circuit breaker tripping rod 23 of the circuit breaker module 2 is driven to operate so that the power connection between the input end 25 and the output end 26 is disconnected.

In the illustrated embodiment, the ground fault detection drive module 1 includes a housing, and a ground fault signal processing assembly 111, a ground fault signal detection assembly 112 coupled to the ground fault signal processing assembly 111, and a drive assembly 106, contained in the housing. The ground fault signal processing assembly 111 includes, for example, at least a control circuit board 111a. The ground fault signal detection assembly 112 includes, for example, at least a ground fault detection coil to detect a ground fault signal in current-carrying wires that pass therethrough. The housing has a cavity to accommodate and fix the ground fault detection coil. The housing is also provided with a through hole, which is concentric with the inner hole of the ground fault detection coil. As shown in FIG. 1B, the input end 25 and the output end 26 are configured to be coupled to a power supply (LINE) and an electrical load (LOAD) via current-carrying wires (hot wire HOT, neutral wire WHITE), respectively, and the through hole of the housing is suitable for the current-carrying wire to pass through. In addition, the ground fault detection drive module 1 also includes power input terminals 100 for providing power to the ground fault detection drive module. Depending on different needs, the power input terminals 100 may be a connecting plates or a connecting terminals.

The ground fault detection drive module 1 also includes an operating assembly. Referring to FIGS. 1B and 2B, the operating assembly at least includes a test assembly to generate a simulated leakage signal and a reset assembly to re-connect the input end and the output end. The test assembly may include an electronic component coupled to the ground fault signal processing assembly 111 and a test button 110b to simulate a leakage current to generate a ground fault signal. At least one test hole is provided on the surface of the housing to allow part of the test button 110b to pass through. The reset assembly may include an electronic component coupled to the ground fault signal processing assembly 111 and a reset button 110a. At least one reset hole is provided on the surface of the housing to allow part of the reset button 110a to pass through.

In some embodiments, the ground fault detection drive module 1 may further include a display assembly 115 to display the working status of the device. Referring to FIGS. 1B and 2B, the display assembly may, for example, include a status indicator light coupled to the ground fault signal processing assembly 111, and the surface of the housing may be provided with at least one display window to allow the display signal of the display assembly to pass through the housing. An alarm display is provided when a ground fault occurs by allowing the user to visually observe the status indicator light in the display window. After the fault is cleared, the alarm display can be cleared by pressing the reset button 110a. Advantageously, the reset assembly is configured such that, when the input and output ends are in a disconnected state due to a ground fault or a simulated ground fault and the display assembly 115 is in an alarm display state, the input end and the output end are unable to be re-connected by moving the operating handle 21 to its final connecting position again; in this condition, it is necessary to operate the reset button 110a after the ground fault is eliminated, to clear the fault alarm state, and then move the operating handle 21 to its final connecting position again to place the input and output ends in the connected (closed) state again.

The drive assembly 106 is configured to, in response to the control of the ground fault signal processing assembly 111, drive the circuit breaker tripping rod to move from its second position to its first position. The drive assembly 106 may include a switch 106e and a tripping coil assembly 106a coupled to each other, and the switch 106e is mechanically linked to the circuit breaker tripping rod 23. The drive assembly 106 also includes a lever 106b mechanically linked to the tripping coil assembly 106a. The lever 106b is configured to drive the circuit breaker module 2, that is, the lever 106b has a first position separated from the circuit breaker tripping rod 23 and a second position abutting against the circuit breaker tripping rod 23 in response to the driving of the tripping coil assembly 106a. Specifically, when the ground fault signal detection assembly 112 detects a ground fault signal, the tripping coil assembly 106a is controlled to move by the control circuit board 111a, which in turn drives the lever 106b to move the circuit breaker tripping rod 23 to its first position, so that the input and output ends are disconnected, as will be described in detail below.

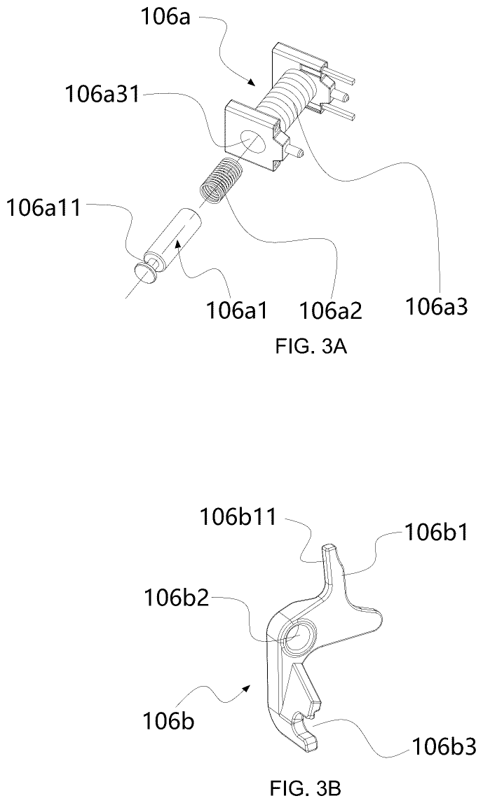

FIGS. 3A and 3B respectively show exploded views of the tripping coil assembly 106a and the lever 106b of the drive assembly 106.

The tripping coil assembly 106a includes an iron core 106a1, an iron core spring 106a2, and a coil winding 106a3. The coil winding 106a3 is coupled to the ground fault signal processing assembly 111 and configured to generate a magnetic field in a power-on state and remove the magnetic field in a power-off state in response to the control of the ground fault signal processing assembly 111. The coil winding 106a3 has a center hole 106a31 for the iron core 106a1 to be inserted. The iron core 106a1 passes through the coil winding 106a3 and is attached to the lever 106b at one end, while the other end abuts against the iron core spring 106a2. In response to the power-on state or the power-off state of the coil winding 106a3, the iron core 106a1 reciprocates in the center hole 106a31 of the coil winding 106a3 under the action of the magnetic force of the coil magnetic field and the elastic force of the iron core spring 106a2, thereby driving the lever 106b to move.

The lever 106b has a tab 106b1 for driving the circuit breaker tripping rod 23 so that the input and output ends of the circuit breaker module are switched from the connected state to the disconnected state. Advantageously, the lever 106b also has a pivot hole 106b2 attached to the housing of the ground fault detection drive module 1, for example, attached to a pivot shaft 105a shown in FIG. 2B, so that the lever 106b can pivot. In this way, the lever 106b is configured to pivot around its pivot hole 106b2 with the movement of the iron core 106a1. Specifically, an iron core groove 106a11 is provided at the end of the iron core 106a1, and the lever 106b is correspondingly provided with a snap-fitting notch 106b3 to snap-fit with the iron core groove 106a11, and is mechanically linked to the iron core 106a1 to move (pivot) to the first position or the second position. That is, when the coil winding 106a3 is energized, a magnetic field is generated to drive the iron core 106a1 to move into the center hole 106a31, thereby driving the lever 106b to pivotally move to the second position abutting against the circuit breaker tripping rod 23. Conversely, when the coil winding 106a3 is de-energized and the magnetic field disappears, under the action of the rebound force of the iron core spring 106a2, the iron core 106a1 together with the lever 106b returns to the initial position, that is, the lever 106b pivots to the first position separated from the circuit breaker tripping rod 23. As shown in FIG. 3B, the tab 106b1 of the lever 106b may be provided with a pushing surface 106b11, and the pivoting movement of the lever 106b will cause the pushing surface 106b1 to abut against the circuit breaker tripping rod 23 and drive the circuit breaker tripping rod 23 to move from its second position to its first position.

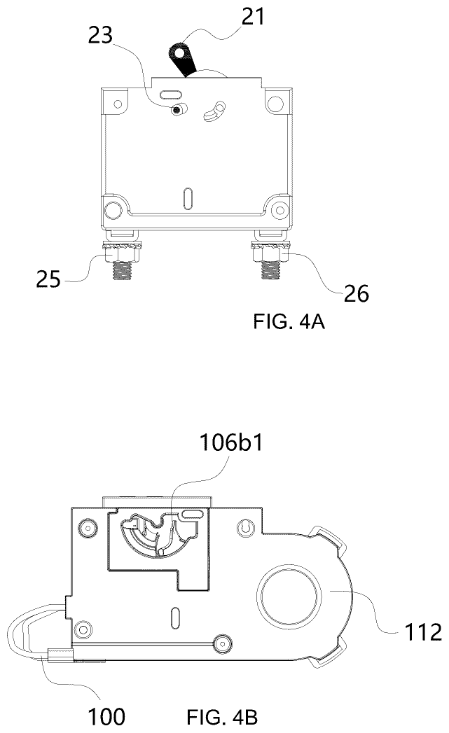

FIGS. 4A and 4B respectively show the mating surfaces of the circuit breaker module and the ground fault detection drive module, where the mating surface of the circuit breaker module is provided with an opening through which the circuit breaker tripping rod 23 extends, and the mating surface of the ground fault detection drive module is provided with an opening through which the lever of the drive assembly extends, so that the ground fault detection drive module 1 is attached and mechanically linked to the circuit breaker module 2, that is, the lever is configured to drive the circuit breaker tripping rod 23. FIG. 4B shows the tab 106b1 of the lever 106b.

As described above, in embodiments of the present invention, the drive assembly 106 includes a switch 106e, which may be coupled to the operating assembly, specifically, coupled to the test assembly. Depending on different needs, the switch may include, for example and without limitation, a contact arm that achieves connection and disconnection through contact terminals. Referring to FIGS. 2B and 5A to 7B, the switch 106e is configured to be mechanically linked to the circuit breaker tripping rod 23, and can achieve reliable and safe connection or disconnection between the input end 25 and the output end 26 by cooperating with the tripping coil assembly 106a and the lever 106b of the drive assembly 106. By appropriately arranging the relationship between the switch state and the amount of travel of the circuit breaker tripping rod, the circuit breaker tripping rod can keep the switch open and closed at appropriate times when it moves from its first position to its second position, and when the lever is driven by the tripping coil assembly, it can drive the circuit breaker module to trip and disconnect the switch, thereby avoiding overheating and damage of the tripping coil winding due to long-term power-on.

Specifically, when the input end 25 and the output end 26 is desired to be connected and the operating handle 21 is moved (e.g. manually by a user) from its initial disconnecting position to its final connecting position, the switch 106e is first in a closed state. At this time, if the ground fault signal detection assembly 112 detects a ground fault signal, the control circuit board 111a can directly control the tripping coil assembly 106a to operate, which drives the lever 106b to place the circuit breaker tripping rod 23 in its first position. At this time, even when the operating handle 21 continues to be moved to its final connecting position, the input end 25 and the output end 26 cannot be connected, thereby avoiding danger caused by mis-operation. In particular, in some embodiments, for example, when the movement of the operating handle 21 from the final connecting position to the initial disconnecting position is obstructed, if the ground fault signal detection assembly 112 detects a ground fault signal, it can still control the lever 106b to operate to drive the circuit breaker tripping rod 23 to move from its second position to its first position, thereby disconnecting the input end 25 from the output end 26, and at the same time placing the switch 106e in an open state. This avoids the problem of inability to disconnect the power connection due to obstruction of the operating handle 21, and improves the stability and reliability of the ground fault detection drive module.

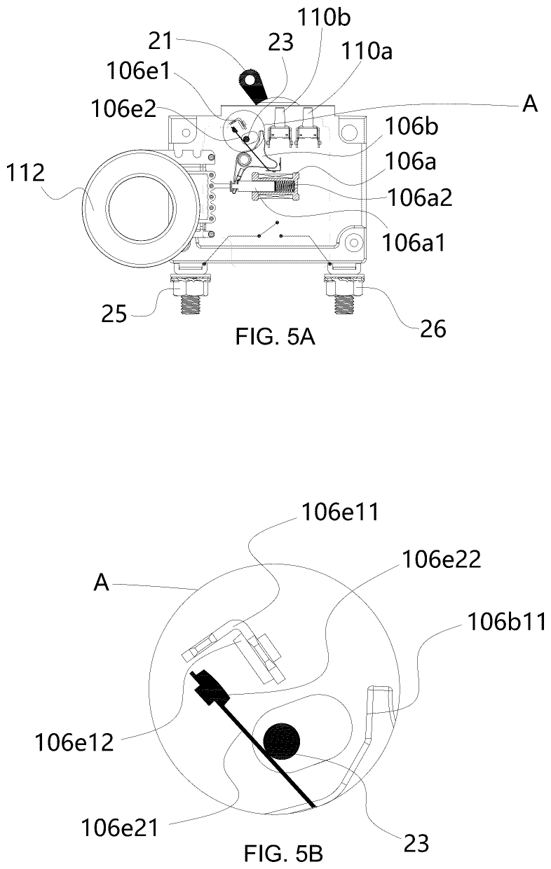

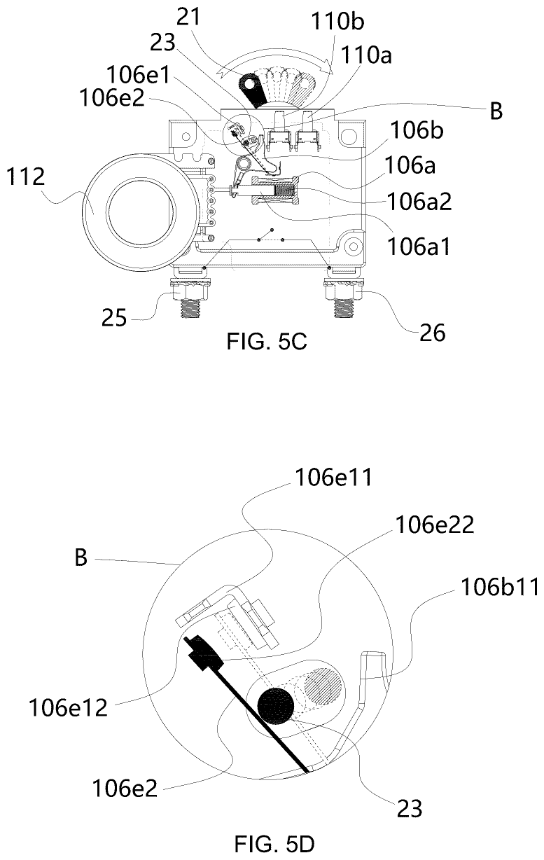

In some embodiments, the switch 106e is configured to be in an open state when the circuit breaker tripping rod 23 moves from its first position toward its second position before reaching a first intermediate position, and in a closed state when it continues to move toward its second position but before reaching a second intermediate position. FIG. 5A shows an initial state in which the operating handle 21 is in the initial disconnecting position and the circuit breaker tripping rod 23 is in its first position. FIG. 5B shows a connected state in which the operating handle 21 moves in the direction of the arrow from the initial disconnecting position to the final connecting position and the circuit breaker tripping rod 23 is in its second position. The moving path of the operating handle 21 (and the corresponding moving path of the circuit breaker tripping rod 23) is divided into multiple stages, such as the four stages (with three intermediate positions) schematically shown in FIG. 5B. According to different needs, the first intermediate position may correspond to one-fourth of the total amount of travel of the circuit breaker tripping rod from its first position to its second position, and the second intermediate position may correspond to an amount of travel greater than that of the first intermediate state but less than the total amount of travel (i.e. the second intermediate position is between the first intermediate position and the second position). It should be understood that the first intermediate position can be adjusted accordingly depending on different needs.

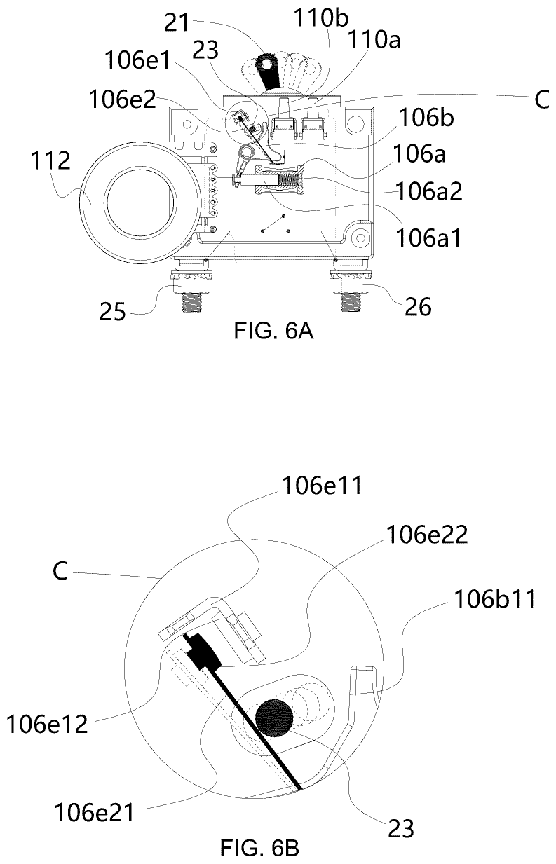

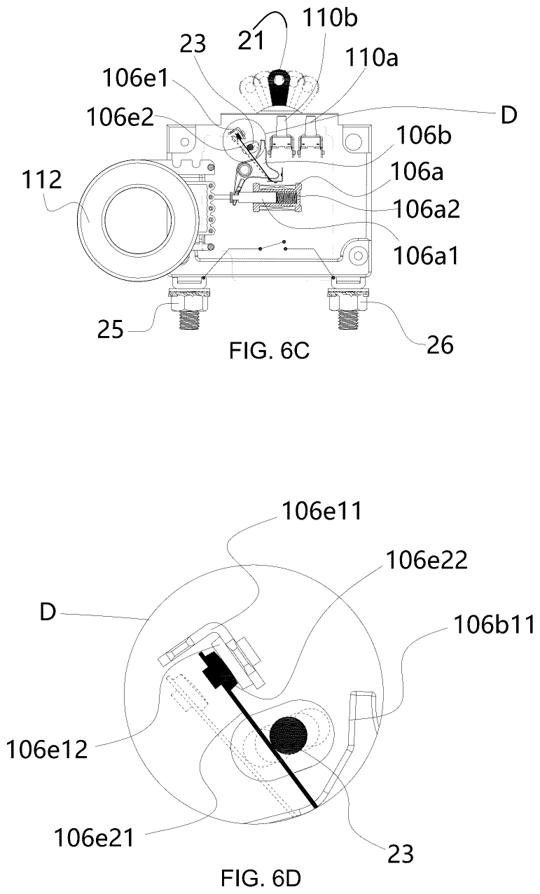

Advantageously, the switch 106e is configured as a normally closed switch which is in the open state when subjected to an external force and returns to the closed state after the external force is removed. In embodiments of the present invention, the external force is exerted by the circuit breaker tripping rod 23. In some embodiments, the switch 106e includes a stationary contact assembly 106e1 and a moving contact assembly 106e2. As shown in FIG. 6B or FIG. 6D, the stationary contact assembly 106e1 includes a stationary contact plate 106e11 and a stationary contact terminal 106e12 fixed on the stationary contact plate 106e11; the moving contact assembly 106e2 includes an elastic moving contact plate 106e21 and a moving contact terminal 106e22 fixed to one end of the elastic moving contact plate 106e21. The elastic moving contact plate 106e21 is mechanically linked to the circuit breaker tripping rod 23 so that the moving contact terminal 106e22 and the stationary contact terminal 106e12 are either separated from each other or contact each other, thereby placing the switch 106e in an open state or a closed state. In the initial disconnected state shown in FIG. 5A, the elastic moving contact plate 106e21 of the moving contact assembly 106e2 is disconnected and separated from the stationary contact assembly 106e1 due to the abutment of the circuit breaker tripping rod 23. In the connected state shown in FIG. 5B, the circuit breaker tripping rod 23 is in its second position, and the moving contact assembly 106e2 and the stationary contact assembly 106e1 contact each other and are in a closed state. In some embodiments, a position limiting block (not shown in the figure) may be provided on the housing, located on a side of the elastic moving contact plate 106e21 away from the stationary contact assembly 106e1 to limit the movement of the elastic moving contact plate.

FIGS. 6A and 6B show the states of the components when the circuit breaker tripping rod 23 of the circuit breaker module is at the first intermediate position (e.g., at one-quarter of the total amount of travel). As shown in FIG. 6B, at the first intermediate position, the elastic moving contact plate 106e21 of the moving contact assembly 106e2 of the switch 106e is still in the disconnected state due to the abutment of the circuit breaker tripping rod 23; the moving contact terminal 106e22 is separated from the stationary contact terminal 106e12, and the input end 25 and the output end 26 are not yet connected at this time.

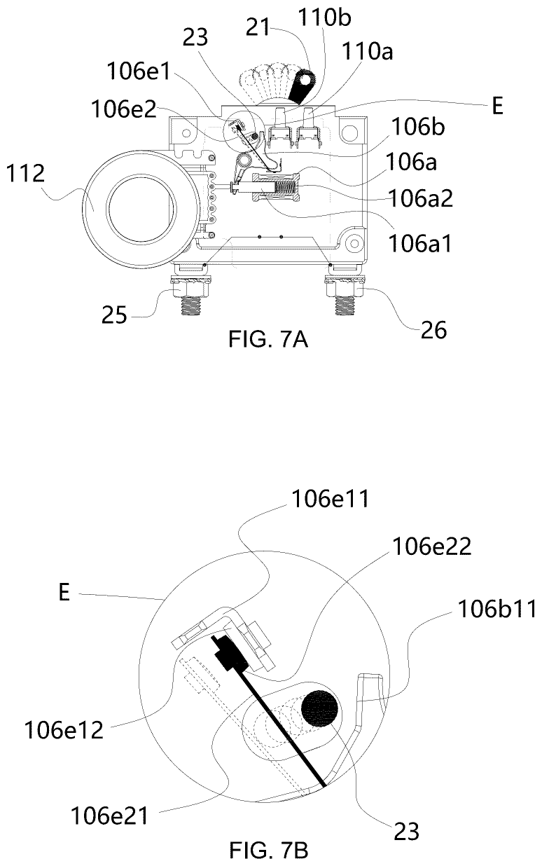

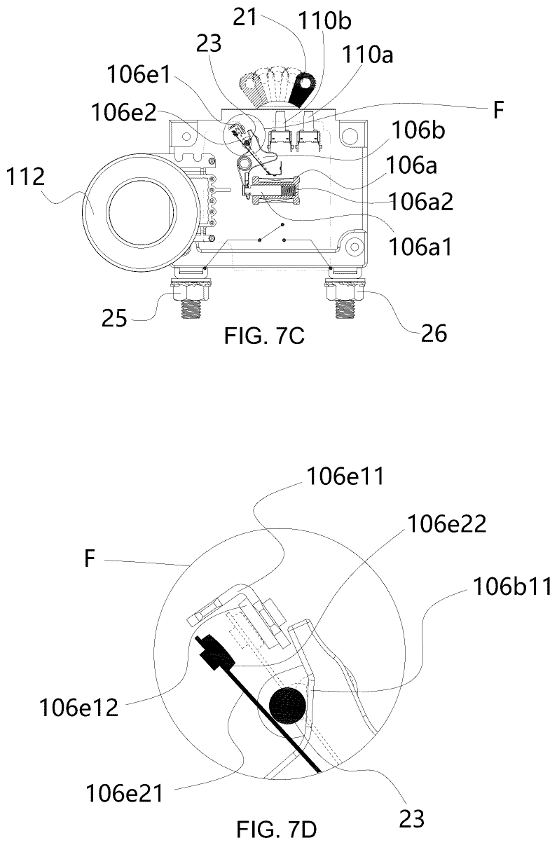

When the operating handle 21 drives the circuit breaker tripping rod 23 to continue to move, if the ground fault signal detection assembly 112 does not detect a ground fault signal or a ground fault signal simulated by the test assembly, the operating handle 21 can be moved without hinderance, while driving the circuit breaker tripping rod 23 to move to its second position, so that the input end and the output end are connected. During this process, before the circuit breaker tripping rod 23 moves to the second intermediate position, the second intermediate position corresponding to, for example, one half of its total amount of travel from its first position to its second position, as shown in FIG. 6C, before the input end 25 is connected with the output end 26 (that is, before the circuit breaker tripping rod 23 has moved to its second position), the switch 106e is already in a closed state. At this time, as shown in FIG. 6D, the moving contact terminal 106e22 is engaged with the stationary contact terminal 106e12. Thereafter, the operating handle 21 continues to move until the circuit breaker tripping rod 23 moves to its second position, so that the input end 25 is connected with the output end 26, as shown in FIG. 7A. Advantageously, the switch 106e is configured such that when in the closed state, the elastic moving contact plate 106e21 maintains elastic deformation to provide a contact pressure to maintain the contact between the moving contact terminal 106e22 and the stationary contact terminal 106e12.

If the ground fault signal detection assembly 112 detects a ground fault signal and sends an action signal, the feedback data is sent to the ground fault signal processing assembly 111. The ground fault signal processing assembly 111 compares the leakage current feedback data with a preset value. If the leakage current is less than the preset value, the drive assembly 106 is not controlled to act. If the leakage current is greater than the preset value, the drive assembly 106 is controlled to act. Specifically, when the drive assembly 106 is controlled to act, the coil winding 106a3 of the tripping coil assembly 106a is energized and generates a magnetic field to drive the iron core 106a1 to drive the lever 106b to pivot synchronously, until the tab 106b1 of the lever 106b abuts against the circuit breaker tripping rod 23 and drives the circuit breaker tripping rod 23 to move to its first position, preventing the input end 25 from being connected to the output end 26. Meanwhile, due to the abutment of the circuit breaker tripping rod 23, the moving contact terminal 106e22 of the moving contact assembly 106e2 is separated from the stationary contact terminal 106e12 of the stationary contact assembly 106e1, and even if the operating handle 21 is moved to its final connecting position, the input end and the output end cannot be connected, as shown in FIG. 7B. When detecting the ground fault signal simulated by the test assembly, the operation is similar and will not be described in detail here.

In some cases, when the operating handle 21 is in its final connecting position as shown in FIG. 7B and cannot move freely due to external reasons, if the ground fault signal detection assembly detects a ground fault signal or the test button is pressed, the ground fault detection drive module can still cause the lever 106b of the drive assembly 106 to move, thereby driving the circuit breaker tripping rod 23 to its first position, disconnecting the input end from the output end, and placing the switch 106e in an open state.

When the input and output ends are disconnected from each other due to the ground fault signal detection assembly detecting a ground fault signal or the test button being pressed, if the power connection between the input and output ends needs to be reconnected, the ground fault alarm state needs to be cleared by operating the reset assembly after eliminating the ground fault, before the operating handle 21 can be operated to connect the power connection between the input and output ends. In this way, the ground fault detection circuit breaker device according to embodiments of the present invention can drive the circuit breaker to trip in the case of a leakage fault through the cooperation of the ground fault signal processing assembly, the ground fault signal detection assembly, the drive assembly, the operating assembly, and the display assembly, etc. The device is suitable for a variety of electrical equipment, improves the safety of electricity use, and can be applied to various application scenarios.

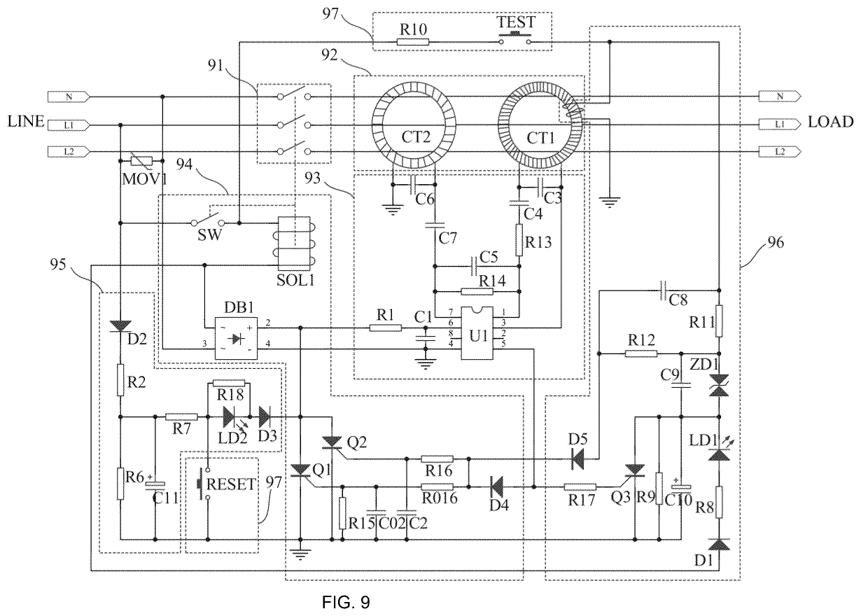

Referring to FIG. 9, embodiments of the present invention provide a ground fault detection circuit breaker device, which includes: an input end and an output end, respectively coupled to a power supply LINE and an electrical load LOAD, and current-carrying wires L1, L2, and N between the input and output ends; a circuit breaker unit 91, configured to disconnect and connect the power connection between the input end and the output end; a ground fault signal detection unit 92, including at least a ground fault detection coil CT1 to detect leakage current on the current-carrying wires L1, L2, and N; a ground fault signal processing unit 93, including at least a ground fault detection chip U1 to determine whether the leakage current exceeds a preset value, and to generate a ground fault signal when the leakage current exceeds the preset value; a drive unit 94, including a switch SW, a tripping coil assembly SOL1, and semiconductor switches (e.g. silicon controlled rectifiers or SCR) Q1/Q2 coupled to each other, the drive unit 94 being configured to drive the circuit breaker unit 91 to operate in response to the ground fault signal to disconnect the input end from the output end. The ground fault detection circuit breaker device further includes a trip holding unit 95, which includes at least a holding capacitor C11, which is configured to keep the semiconductor switches Q1/Q2 in a conducting state.

In some embodiments, the trip holding unit 95 may further include a fault indicator (light emitting diode) LD2, which is configured to issue a leakage fault indication in response to the ground fault signal.

In some embodiments, the ground fault detection circuit breaker device may also include a self-test unit 96, which is coupled to the drive unit 94 and configured to periodically test whether the ground fault signal processing unit 93 is functioning normally, and generate a self-test fault signal when the ground fault signal processing unit 93 fails to function normally.

In some embodiments, the ground fault detection circuit breaker device may further include an operating unit 97, which includes at least a test button TEST coupled to the switch SW to generate a simulated leakage signal and a reset button RESET to restore the semiconductor switches Q1/Q2 to a non-conducting state.

In normal operation, a current flows through the current-carrying wire L1, switch SW, tripping coil assembly SOL1, and diode bridge DB1 (L1-SW-SOL1-DB1) to supply power to the leakage detection chip U1. When the fault detection coil CT1 detects a leakage current on the current-carrying wires L1, L2, or N, a leakage signal is generated at the secondary side, and is processed and compared by the leakage detection chip U1.

When the leakage current on L1, L2, or N is greater than the preset value, the drive pin (pin 5) of the leakage detection chip U1 outputs a high voltage level (the ground fault signal), and the diode D4 and resistors R16/R016 drive the SCRs Q1/Q2 (semiconductor switches) to conduct. At this time, a current flows into the ground through the current-carrying wire L1, switch SW, tripping coil assembly SOL1, DB1, SCR Q1/Q2 (L1-SW-SOL1-DB1-Q1/Q2), and the tripping coil assembly SOL1 is energized and generates a large magnetic field, driving the circuit breaker unit 91 to disconnect the power connection between the input and output ends, and at the same time driving the switch SW to open, so that the tripping coil assembly SOL1 loses power, preventing the tripping coil assembly SOL1 from being burned by long-term power-on.

When the SCRs Q1/Q2 are conducting, a current also flows through L1-D2-R2, and after being filtered by the holding capacitor C11, it flows into the ground through R7-LD2-D3-Q1/Q2, lighting up the light-emitting diode LD2 (fault indicator) to indicate a ground fault, and keeping the SCRs Q1/Q2 in the conducting state. When the circuit breaker unit 91 is operated to close, the switch SW is closed earlier than the circuit breaker unit 91. When the switch SW is closed, since the SCRs Q1/Q2 remain in the conducting state, the current passes through the tripping coil assembly SOL1 again, and generates a magnetic field to drive the circuit breaker unit 91 to disconnect, so that the circuit breaker unit 91 cannot complete the closing action, and the input and output ends remain in the disconnected state.

When the reset button RESET is operated, the current rectified by the holding capacitor C11 flows directly into the ground from RESET, and no longer flows through Q1/Q2, causing Q1/Q2 to become non-conductive. When the circuit breaker unit 91 is operated to close again, no current flows through the tripping coil assembly SOL1, and the circuit breaker unit 91 will not be driven to trip again. Thus, the circuit breaker unit 91 is closed successfully, connecting the power connection between the input end and the output end.

In normal operation, when the test button TEST is manually pressed, a simulated leakage current flows through L1-SW-R10-TEST-CT1-ground. When the manually generated simulated leakage current signal is detected by the fault detection coil CT1 and processed and compared by the leakage detection chip U1, the drive pin (pin 5) of the leakage detection chip U1 outputs a high voltage level, and the diode D4 and resistors R16/R016 drive the SCRs Q1/Q2 to become conductive. At this time, a current flows into the ground through L1-SW-SOL1-DB1-Q1/Q2, so the tripping coil assembly SOL1 is energized and generates a large magnetic field, driving the circuit breaker unit 91 to disconnect the power connection between the input and output ends. This indicates that the ground fault detection circuit breaker device is functioning properly. On the contrary, when the test button TEST is pressed, if the circuit breaker unit 91 does not disconnect the power connection between the input and output ends, it indicates that the ground fault detection circuit breaker device has lost its function and needs to be replaced immediately.

Due to the leakage self-test unit 96, the ground fault detection circuit breaker also has a self-test function. A current charges the capacitor C10 through L1-D1-R8. When the voltage on the upper end of the capacitor C10 exceeds the trigger voltage of the trigger diode ZD1, the trigger diode is turned on (conductive), and a current flows through ZD1-R11-CT1-ground to generate a simulated leakage current, and also charges capacitor C8 through 12. The ground fault detection coil CT1 detects the simulated leakage current; after the signal from CT1 is processed by the leakage detection chip U1, a high voltage level is output at the drive pin (pin 5). A current charges capacitors C2/C02 through resistors R16/R016, and also triggers semiconductor switch Q3 to become conductive through R17. As a result, the voltage on the upper end of the capacitor C10 decreases rapidly. The trigger diode ZD1 is no longer triggered to conduct, and the drive pin of chip U1 stops outputting the high level. Due to the short triggering time, the voltages on the upper ends of capacitors C2/C02 and C8 are low at this time, which are not enough to cause Q1/Q2 to become conductive, and the circuit breaker unit 91 remains in a closed state. But when a component failure occurs, causing the drive pin of the leakage detection chip U1 to be unable to output the high voltage level when the trigger diode ZD1 sends out the simulated leakage current, ZD1 will remain conductive for a long time, causing the voltage on the upper end of C8 to continue to rise, and eventually generating a self-test fault signal, triggering Q1/Q2 to turn on through D5-R16/R016. As a result, a current flows into the ground through L1-SW-SOL1-DB1-Q1/Q2. The tripping coil assembly SOL1 generates a magnetic field, causing the circuit breaker unit 91 to disconnect the power connection between the input and output ends, thereby completing the self-test operation.

It should be understood that the embodiments shown in the drawings only illustrate the preferred shapes, sizes and spatial arrangements of the various components of the ground fault detection circuit breaker. These illustrations do not limit the scope of the invention; other shapes, sizes and spatial arrangements may be used without departing from the spirit of the invention.

It will be apparent to those skilled in the art that various modification and variations can be made in the embodiments of the present invention without departing from the spirit or scope of the invention. Thus, it is intended that the present invention cover modifications and variations that come within the scope of the appended claims and their equivalents.

1. A ground fault detection circuit breaker comprising:
a circuit breaker module, having an input end configured to be coupled to a power supply, an output end configured to be coupled to an electrical load, and a circuit breaker tripping rod, the circuit breaker tripping rod having a first position in a disconnected state and a second position in a connected state, configured to respectively disconnect and connect a power connection between the input end and the output end; and
a ground fault detection drive module, including a housing, a ground fault signal processing assembly, a ground fault signal detection assembly coupled to the ground fault signal processing assembly, and a drive assembly coupled to the ground fault signal processing assembly, wherein the ground fault signal processing assembly, the ground fault signal detection assembly and the drive assembly are disposed in the housing, wherein the drive assembly is configured to drive the circuit breaker tripping rod to move from the second position to the first position in response to control of the ground fault signal processing assembly,
wherein the drive assembly includes a switch and a tripping coil assembly coupled to each other, wherein the switch is mechanically linked to the circuit breaker tripping rod, and is configured to be in an open state when the circuit breaker tripping rod moves from the first position toward the second position before reaching a first intermediate position, and be in a closed state when the circuit breaker tripping rod moves further and before reaching a second intermediate position.

2. The ground fault detection circuit breaker of claim 1, wherein the first intermediate position corresponds to one-fourth of a total amount of travel of the circuit breaker tripping rod from the first position to the second position, and the second intermediate position is located between the first intermediate position and the second position.

3. The ground fault detection circuit breaker of claim 1, wherein the switch is a normally closed switch which is in the open state when subjected to a pushing force by the circuit breaker tripping rod and returns to the closed state after the pushing force is removed.

4. The ground fault detection circuit breaker of claim 3, wherein the switch includes a stationary contact assembly and a moving contact assembly, wherein the stationary contact assembly includes a stationary contact plate and a stationary contact terminal fixed on the stationary contact plate, the moving contact assembly includes an elastic moving contact plate and a moving contact terminal fixed to one end of the elastic moving contact plate, and wherein the elastic moving contact plate is mechanically linked to the circuit breaker tripping rod to cause the moving contact terminal and the stationary contact terminal to either be separated from each other or contact each other, thereby placing the switch in the open state or the closed state.

5. The ground fault detection circuit breaker of claim 4, wherein the switch is configured such that when in the closed state, the elastic moving contact plate maintains elastic deformation to provide a contact pressure to maintain the contact between the moving contact terminal and the stationary contact terminal.

6. The ground fault detection circuit breaker of claim 4, wherein the housing includes a position limiting block, located on a side of the elastic moving contact plate away from the stationary contact assembly, and configured to limit a movement of the elastic moving contact plate.

7. The ground fault detection circuit breaker of claim 1, wherein the drive assembly further includes a lever mechanically linked to the tripping coil assembly, wherein the lever is configured to be in a first position separated from the circuit breaker tripping rod and or in a second position abutting against the circuit breaker tripping rod in response to driving action of the tripping coil assembly.

8. The ground fault detection circuit breaker of claim 7, wherein the trip coil assembly drives the lever to move in response to control of the ground fault signal processing assembly; and/or the trip coil assembly includes a coil winding coupled to the ground fault signal processing assembly and an iron core and a spring disposed in the coil winding, wherein the iron core is configured to reciprocate in the coil winding.

9. The ground fault detection circuit breaker of claim 8, wherein the lever has a snap-fitting notch configured to snap-fit with the iron core, and is mechanically linked to the iron core to pivot to a first position or a second position; and/or the lever has a pivot hole attached to the housing of the ground fault detection drive module, wherein the lever is configured to pivot around the pivot hole.

10. The ground fault detection circuit breaker of claim 9, wherein the lever has a tab with a pushing surface, and wherein a pivoting movement of the lever causes the pushing surface to abut against the circuit breaker tripping rod and drive the circuit breaker tripping rod to move from its second position to its first position to place the switch in the open state.

11. The ground fault detection circuit breaker of claim 1, wherein the ground fault signal detection assembly includes at least one ground fault detection coil configured to detect a ground fault signal in the current-carrying wires which pass therethrough, and wherein the housing has a cavity to accommodate and fix the ground fault detection coil.

12. The ground fault detection circuit breaker of claim 11, wherein the input end and the output end are coupled respectively to the power supply and the electrical load by the current-carrying wires.

13. The ground fault detection circuit breaker of claim 12, wherein the housing further includes a through hole, which is concentric with an inner hole of the ground fault detection coil and configured to for the current-carrying wires to pass through.

14. The ground fault detection circuit breaker of claim 1, wherein the ground fault detection drive module further includes power input terminals for providing power to the ground fault detection drive module.

15. The ground fault detection circuit breaker of claim 1, wherein the ground fault detection drive module further includes an operating assembly, the operating assembly including at least a test assembly coupled to the switch and configured to generate a simulated leakage signal and a reset assembly configured to re-connect the input end and the output end.

16. The ground fault detection circuit breaker of claim 1, wherein the ground fault detection drive module includes a control circuit board for mounting the ground fault signal processing assembly.

17. The ground fault detection circuit breaker of claim 1, wherein the ground fault detection drive module further includes a display assembly configured to display a working status of the ground fault detection circuit breaker.

18. The ground fault detection circuit breaker of claim 1, wherein the circuit breaker module and the ground fault detection drive module are connected and fixed to each other by a fixing device.

19. The ground fault detection circuit breaker of claim 18, wherein the fixing device includes at least one of rivets, bolts, screws, snaps, connecting plates, and fixing blocks.

20. A ground fault detection circuit breaker, comprising:
an input end and an output end, configured to be respectively coupled to a power supply and an electrical load;
current-carrying wires connecting the input end and the output end;
a circuit breaker unit, configured to disconnect and connect a power connection between the input end and the output end;
a ground fault signal detection unit, including at least a ground fault detection coil configured to detect a leakage current on the current-carrying wires;
a ground fault signal processing unit, including at least a ground fault detection chip configured to determine whether the leakage current exceeds a preset value, and to generate a ground fault signal when the leakage current exceeds the preset value;
a drive unit, including a switch, a tripping coil assembly, and semiconductor switches coupled to each other, the drive unit being configured to drive the circuit breaker unit to operate in response to the ground fault signal to disconnect the input end from the output end; and
a trip holding unit, which includes at least a holding capacitor, the holding capacitor being configured to keep the semiconductor switches in a conducting state.

21. The ground fault detection circuit breaker of claim 20, wherein the trip holding unit further included a fault indicator, configured to issue a leakage fault indication in response to the ground fault signal.

22. The ground fault detection circuit breaker of claim 20, further comprising a self-test unit, coupled to the drive unit and configured to periodically test whether the ground fault signal processing unit is functioning normally, and generate a self-test fault signal when the ground fault signal processing unit fails to function normally.

23. The ground fault detection circuit breaker of claim 20, further comprising an operating unit, including at least a test button coupled to the switch and configured to generate a simulated leakage signal and a reset button configured to restore the semiconductor switches to a non-conducting state.
